(19) United States
(12) Patent Application Publication
(10) Pub. No.: US 2024/0247399 A1
(43) Pub. Date: Jul. 25, 2024

(54) WATER-COOLED SCREEN FOR IMPROVING PULLING RATE OF SILICON CRYSTAL AND MOULD FOR PREPARING THE SAME

(71) Applicant: TCL ZHONGHUAN RENEWABLE ENERGY TECHNOLOGY CO., LTD, Tianjin (CN)

(72) Inventors: Xiaodong LI, Tianjin (CN); Lei AN, Tianjin (CN)

(73) Assignee: TCL ZHONGHUAN RENEWABLE ENERGY TECHNOLOGY CO., LTD, Tianjin (CN)

(21) Appl. No.: 18/040,098

(22) PCT Filed: Nov. 28, 2022
(86) PCT No.: PCT/CN2022/134814

§ 371 Date: Jan. 31, 2023

(30) Foreign Application Priority Data
Mar. 31, 2022 (CN) 202220731361.3

(51) Int. Cl. C30B 15/02; C30B 15/00; C30B 15/20; C30B 29/06

(52) U.S. Cl. CPC C30B 15/02; C30B 15/002; C30B 15/20; C30B 29/06

(57) ABSTRACT

The present disclosure provides raw material re-feeding apparatus and monocrystal manufacturing apparatus having the same. The raw material re-feeding apparatus includes a charger body, a storage, a fixed conveyer, a mobile conveyer, and a switching device. The fixed conveyer and the storage are disposed in the charger body, and the fixed conveyer is disposed at a discharging end of the storage for conveying materials. A charging end of the mobile conveyer is aligned with a discharging end of the fixed conveyer, and the mobile conveyer is movable relative to a monocrystal furnace, so that materials flowing out of the fixed conveyer can fall onto the mobile conveyer. The switching device is connected to the charger body and the monocrystal furnace for achieving connection/disconnection between the charger body and the monocrystal furnace.

### CROSS-REFERENCE TO RELATED APPLICATION

This application claims priority to and the benefit of Chinese Patent Application No. 202220731361.3, filed in the China National Intellectual Property Administration on Mar. 31, 2022, the disclosure of which is hereby incorporated by reference in its entirety.

### TECHNICAL FIELD

The present disclosure relates to a technical field of monocrystal production, and in particular to raw material re-feeding apparatus and monocrystal manufacturing apparatus having the same.

### BACKGROUND

With a conventional furnace for pulling-up of a silicon monocrystal, after crystal pulling is completed using raw materials of a furnace, it is necessary to do a lot of complicated preliminary work to prepare for the crystal production of the next furnace, including processes such as stopping the furnace for cooling, scrubbing the furnace, charging, vacuumizing, and melting materials. A lot of time may be wasted for the complicated preliminary work. Although the silicon raw materials can be supplemented by an internal re-feeding device, a large amount of the raw materials cannot be supplemented. Moreover, sputtering of silicon solution may occur during the feeding process.

### SUMMARY

The present disclosure provides external re-feeding apparatus to address at least one of the above problems or other problems in the prior art.

According to an aspect of an embodiment of the present disclosure, there is provided an external re-feeding apparatus provided outside a monocrystal furnace, including a charger body, a storage, a fixed conveyer, a mobile conveyer, a switching device, and a pressure controller, wherein,
each of the fixed conveyer and the storage is provided in the charger body, and the fixed conveyer is provided at a discharge end of the storage for conveying the raw materials;
the mobile conveyer is provided at a discharge end of the fixed conveyer, the mobile conveyer is movable with respect to the monocrystal furnace, and a feed end of the mobile conveyer corresponds to the discharge end of the fixed conveyer, so that the raw materials flowing out of the fixed conveyer may fall onto the mobile conveyer, and the raw materials are conveyed into the monocrystal furnace under the action of the mobile conveyer, so as to feed;
the pressure controller is connected to the charger body for controlling the pressure in the charger body;
the switching device is connected to the charger body and the monocrystal furnace respectively, for achieving connection and disconnection between the charger body and the monocrystal furnace.

According to an embodiment of the present disclosure, a mobile conveyer includes a mobile feeding tube, a mobile vibrator, and a moving device, the mobile vibrator is connected to the mobile feeding tube, and the mobile feeding tube is connected to the moving device. The mobile feeding tube is movable relative to the fixed conveyer under the action of the moving device, and during the moving, the feed end of the mobile feeding tube at least partially corresponds to the discharging end of the fixed conveyer, so that the mobile feeding tube may enter the monocrystal furnace and the feeding is carried out under the action of the mobile vibrator.

According to an embodiment of the present disclosure, a charger body includes a housing and a connecting channel, the connecting channel is connected to the housing, and the housing communicates with the connecting channel, and a discharging end of a mobile feeding tube is provided in the connecting channel.

According to an embodiment of the present disclosure, a mobile conveyer includes a mobile feeding tube, a mobile vibrator and a moving device, the mobile vibrator is connected to the mobile feeding tube, the mobile feeding tube is connected to the charger body, and the charger body is connected to the moving device. The charger body moves toward the monocrystal furnace under the action of the moving device, and the mobile feeding tube may enter the monocrystal furnace and feed under the action of the mobile vibrator.

According to an embodiment of the present disclosure, a charger body includes a housing and a telescopic member, the telescopic member is connected to the housing, and the housing communicates with the telescopic member, and a discharge end of the mobile feeding tube is provided inside the telescopic member.

According to an embodiment of the present disclosure, the fixed conveyer includes a fixed feeding tube and a fixed vibrator, the fixed feeding tube is connected to the fixed vibrator, and the raw materials in the fixed feeding tube is conveyed to the mobile conveyer under the action of the fixed vibrator.

According to an embodiment of the present disclosure, the switching device is a valve.

According to an embodiment of the present disclosure, the pressure controller is a vacuum pump.

According to an embodiment of the present disclosure, a pressure measuring instrument is provided on the charger body.

According to an embodiment of the present disclosure, the external re-feeding apparatus further includes a controller electrically connected to the pressure controller, the fixed conveyer, the mobile conveyer, the storage, and the pressure measuring instrument, respectively, the a controller receives a detection signal from the pressure measuring instrument, and controls the operation of the pressure controller, the fixed conveyer, the mobile conveyer, and the storage.

According to an aspect of an embodiment of the present disclosure, there is provided a raw material re-feeding apparatus provided outside a monocrystal furnace, the raw material re-feeding apparatus includes a charger body; a storage provided in the charger body; a conveyer provided in the charger body and configured to convey raw materials, wherein a feed end of the conveyer is aligned with a discharging end of the storage to receive the raw materials supplied from the storage; a switching device provided between the charger body and the monocrystal furnace and connected to the feeding device main body and the monocrystal furnace, and configured to control connection and disconnection between the charger body and the monocrystal furnace; and a moving device configured to drive the conveyer to move a discharging end of the conveyer from an outside of the monocrystal furnace to an inside of the monocrystal furnace.

According to an aspect of an embodiment of the present disclosure, there is provided a monocrystal manufacturing apparatus including: a monocrystal furnace; and a raw material re-feeding apparatus provided outside the monocrystal furnace, wherein the raw material re-feeding apparatus includes a charger body; a storage provided in the charger body; a conveyer disposed in the charger body and configured to convey raw materials, wherein a feed end of the conveyer is aligned with a discharging end of the storage to receive the raw materials supplied from the storage; a switching device provided between the charger body and the monocrystal furnace and connected to the charger body and the monocrystal furnace, and configured to control connection and disconnection between the charger body and the monocrystal furnace; and a moving device configured to drive the conveyer to move a discharging end of the conveyer from an outside of the monocrystal furnace to an inside of the monocrystal furnace.

According to an aspect of an embodiment of the present disclosure, there is provided a monocrystal manufacturing apparatus including: a monocrystal furnace; and a raw material re-feeding apparatus provided outside the monocrystal furnace, wherein the raw material re-feeding apparatus includes a charger body, a storage, a fixed conveyer, a mobile conveyer, a switching device, and a pressure controller. Both the fixed conveyer and the storage are provided in the charger body, and a feed end of the fixed conveyer is aligned with a discharging end of the storage. A feed end of the mobile conveyer is arranged in alignment with a discharge end of the fixed conveyer, and the mobile conveyer is movable in a direction towards the monocrystal furnace, so that the raw material flowing out of the fixed conveyer may fall onto the mobile conveyer and be conveyed into the monocrystal furnace for feeding under the action of the mobile conveyer. The pressure controller is connected to the charger body for controlling the pressure in the charger body. The switching device is connected to the charger body and the monocrystal furnace, respectively, for achieving connection and disconnection between the charger body and the monocrystal furnace.

With the above-mentioned technical solution, the external re-feeding apparatus is simple in structure, convenient to use, and has the storage, so that the raw materials may be stored, thereby meeting the requirements of continuous feeding; the conveyer may move relative to the monocrystal furnace, and may be relatively close to or far away from the monocrystal furnace, so that the discharging end of the conveyer may enter the monocrystal furnace when re-feeding, and the raw materials may move along the conveyer to perform re-feeding, thereby realizing continuous feeding of the raw materials, and avoiding waste of work time caused by furnace shutdown; in addition, according to the above-described technical solution, when the raw materials are put into the quartz crucible, impact on the quartz crucible is reduced, and a sputtering phenomenon does not occur in the silicon melt.

### BRIEF DESCRIPTION OF THE DRAWINGS

FIG. 1 is a schematic structural diagram of a raw material re-feeding apparatus according to an embodiment of the present disclosure.

FIG. 2 is a schematic structural diagram of a raw material re-feeding apparatus according to an embodiment of the present disclosure.

FIG. 3 is a schematic structural diagram of a raw material re-feeding apparatus according to another embodiment of the present disclosure.

List of reference signs:

| | |
|---|---|
| 1: Charger body | 2: Storage |
| 3: Fixed vibrator | 4: Fixed feeding tube |
| 5: Mobile feeding tube | 6: Mobile vibrator |
| 7: Switching device | 8: Monocrystal furnace |
| 9: Control screen | 10: Observation window |
| 11: Pressure controller | 12: Mobile connection device |
| 13: Mobile slide rail | 14: External moving device |
| 15: Connecting channel | 16: Telescopic member |
| 17: Housing | |

### DETAILED DESCRIPTION

The present disclosure will now be described more fully hereinafter with reference to the accompanying drawings in which embodiments of the present disclosure are shown. However, the present disclosure may be embodied in different forms and should not be construed as limited to the embodiments set forth herein. Rather, these embodiments are provided so that this disclosure will be thorough and complete, and will fully convey the scope of the invention to those skilled in the art.

Like components will be denoted by like reference numerals. In addition, it should be noted that the drawings may be exaggerated in thickness, scale, and size of the assembly for convenience and clarity of description only. The term “and/or” may include any and all combinations of one or more of the relevant listed items.

It will be understood that although the terms “first”, “second”, etc. may be used here to describe various elements, these elements should not be limited by these terms. These terms are used only to distinguish one element from another. For example, the first element discussed below may be referred to as a second element without departing from the teachings of the present disclosure. Similarly, the second element may also be named the first element. In the present disclosure, the singular is also intended to include the plural unless the context clearly dictates otherwise.

It should be noted that in the embodiments of the present disclosure, the term “re-feeding” refers to the process of putting the raw material used to form the monocrystal into the manufacturing apparatus during operation of the manufacturing apparatus of the monocrystal.

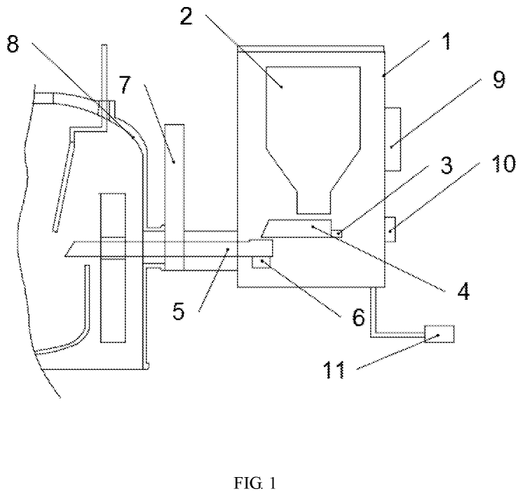

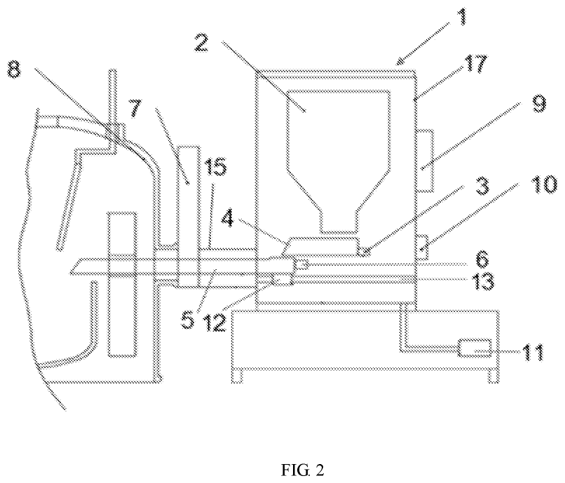

FIGS. 1 and 2 show a schematic structural view of an embodiment of the present disclosure. The present embodiment relates to an external re-feeding apparatus (or a raw material re-feeding apparatus) for re-feeding materials (or raw materials) during a pulling-up monocrystal process. The external re-feeding apparatus includes a storage and a raw material conveyer. The storage and the raw material conveyer cooperate with each other to realize continuous feeding of the raw materials, thereby avoiding waste of work time caused by shutdown.

As shown in FIG. 1, an external re-feeding apparatus is provided outside the monocrystal furnace 8, and the external re-feeding apparatus communicates with the monocrystal furnace 8 so that the external re-feeding apparatus may re-feed the raw materials to the quartz crucible. The external re-feeding apparatus includes a charger body 1, a storage 2, a conveyer, and a switching device 7.

In some embodiments of the present disclosure, the storage 2 is disposed in the charger body 1, and the conveyer is disposed in the charger body 1 and configured to transfer the raw materials. A feed end of the conveyer is aligned with a discharge end of the storage 2 to receive the raw materials supplied by the storage 2.

In some embodiments of the present disclosure, the conveyer includes a fixed conveyer and a mobile conveyer.

Specifically, a fixed conveyer is provided in the charger body 1, is located below the storage 2, and is used for conveying materials. The fixed conveyer comprises a first feed end and a first discharging end, and the first feed end is the feed end of the conveyer, in other words, the first feed end is aligned with the discharge end of the storage 2. The storage 2 is used for storing materials, and a fixed conveyer is provided at the discharge end of the storage 2 so that the materials in the storage 2 flow out of the storage 2 and then fall into the fixed conveyer for conveying the materials.

The mobile conveyer includes a second feed end and a second discharging end. The second feed end is aligned with the first discharging end of the fixed conveyer so that raw materials flowing out of the fixed conveyer may fall onto the mobile conveyer. The mobile conveyer is movable relative to the monocrystal furnace, and the materials are conveyed into the monocrystal furnace 8 by the mobile conveyer for feeding.

In some embodiments of the present disclosure, the switching device 7 is connected to the charger body 1 and the monocrystal furnace 8, respectively, for achieving the connection and disconnection between the charger body 1 and the monocrystal furnace 8. When material re-feeding is required, the switching device 7 is kept open so that the charger body 1 communicates with the monocrystal furnace 8 to perform the re-feeding of the material. When material re-feeding is not required, the switching device 7 is kept closed so that the monocrystal furnace 8 is not communicated with the charger body 1 to ensure smooth crystal pulling of the monocrystal furnace 8.

However, the embodiments according to the present disclosure are not limited to the above description. For example, in some embodiments of the present disclosure, the external re-feeding apparatus may also include a pressure controller 11.

Specifically, the pressure controller 11 is connected to the charger body 1 for controlling the pressure in the charger body 1, and the pressure in the monocrystal furnace 8 coincides with the pressure in the charger body 1 during the material re-feeding so that the pressure in the monocrystal furnace 8 does not change during the material re-feeding.

When the material re-feeding is performed, the pressure controller 11 operates, the inside of the charger body 1 is vacuumed, and the pressure in the charger body 1 is controlled to be consistent with the pressure in the monocrystal furnace 8. When the pressure in the charger body 1 is consistent with the pressure in the monocrystal furnace 8, the switching device 7 is opened, the mobile conveyer operates, the mobile conveyer enters the monocrystal furnace 8, and the second discharging end of the mobile conveyer is located above the quartz crucible. At the same time, the fixed conveyer operates, the storage 2 operates, the materials flow out from the storage 2 and fall into the fixed conveyer, the fixed conveyer conveys the materials to the mobile conveyer, and the materials fall into the quartz crucible, so that the materials are fed again. After the re-feeding of the materials is completed, the mobile conveyer is returned to the original position, and the switching device 7 is turned off to complete the re-feeding of the materials. By using the external re-feeding apparatus, continuous feeding of materials may be realized, and waste of work time caused by shutdown may be avoided. At the same time, during re-feeding of materials, a small amount of continuous re-feeding is performed. When the materials enter the quartz crucible, impact on the quartz crucible is reduced, and a sputtering phenomenon does not occur in the silicon melt.

In addition, the above-mentioned storage 2 has a box-type structure and has an internal storage space for storing materials, so that a large amount of materials may be continuously re-fed. The storage 2 has a feed end for charging and a discharging end for discharging. In some embodiments of the present disclosure, in order to enable the materials in the storage 2 to fall quickly into the fixed conveyer, the storage 2 is vertically placed with the feed end located at the top end of the storage 2 and the discharging end located at the bottom of the storage 2, the discharging end corresponds to the fixed conveyer, the materials flowing out from the discharging end fall directly into the fixed conveyer.

In some embodiments of the present disclosure, a valve is provided at the discharging end of the storage 2 to control the opening or closing of the discharging end, so that the valve is opened when the material re-feeding is required, the material re-feeding is performed, the valve is closed when the material re-feeding is not required, the material does not flow out. The degree of opening of the valve may be adjusted, and the quantity of the materials flowing out may be controlled so that the quantity of the materials flowing out from the storage 2 corresponds to the quantity of the materials conveyed by the fixed conveyer, and the material does not accumulate on the fixed conveyer to cause the material to fall. The valve is an automatic regulating valve, which is a commercially available product, and is selected according to actual requirements, and it is not specifically required herein.

In some embodiments of the present disclosure, the fixed conveyer includes a fixed feeding tube 4 and a fixed vibrator 3. The fixed feeding tube 4 is connected to the fixed vibrator 3. The fixed feeding tube 4 generates vibrations under the action of the fixed vibrator 3, so that materials are conveyed under the action of the vibrations to the mobile conveyer. The fixed feeding tube 4 has a pipe structure. The materials are moved along the length of the fixed feeding tube 4, so that the materials are conveyed. The fixed feeding tube 4 is provided with an opening at a position corresponding to the discharging end of the storage 2, so that the materials flowing out from the storage 2 may fall into the fixed feeding tube 4. The opening has a size larger than that of the discharging end of the storage 2, so that the materials are prevented from falling on the fixed feeding tube 4. The discharging end (that is, the first discharging end) of the fixed feeding tube 4 is in communication with the outside. This allows the materials in the fixed feeding tube 4 to enter the mobile conveyer. The fixed vibrator 3, for example, a vibrator, is fixedly mounted on the fixed feeding tube 4, and vibrates the fixed feeding tube 4 by the vibrating of the vibrator, so that the materials located in the fixed feeding tube 4 vibrates. According to the mechanical resonance principle, the materials are conveyed in the fixed feeding tube 4, and thus the materials are conveyed. The vibrator is a commercially available product and is selected according to actual requirements, and no specific requirements are made herein.

Both the fixed conveyer and the storage 2 are mounted inside the charger body 1, and the storage 2 is fixedly mounted inside the charger body 1 by a mounting frame. A supporting table is provided inside the charger body 1, and the fixed conveyer is mounted on the supporting table. The fixed conveyer does not interfere with the charger body 1 and the storage 2 when the materials are conveyed through the fixed vibrator 3, thereby ensuring the stability of the storage 2 and the charger body 1.

In some embodiments of the present disclosure, the above-described mobile conveyer includes a mobile feeding tube 5, a mobile vibrator 6, and a moving device. The mobile vibrator 6 is connected to the mobile feeding tube 5, and the mobile feeding tube 5 is connected to the moving device. The mobile feeding tube 5 may be moved relative to the charger body 1 by the moving device, and the mobile feeding tube 5 may enter the monocrystal furnace 8 to perform the feeding by the mobile vibrator 6. The mobile feeding tube 5 is movable with respect to the fixed feeding tube 4, and the mobile feeding tube 5 overlaps at least partially with the fixed feeding tube 4 during the moving process, so that the materials may accurately enter the mobile feeding tube 5, avoiding that the materials do not fall into the mobile feeding tube 5. The mobile feeding tube 5 is of a pipe structure and has an opening at the charging end of the mobile feeding tube 5. The opening has a length such that the opening of the mobile feeding tube 5 always corresponds to the discharging end of the fixed feeding tube 4 during the moving process, and the materials flowing out of the fixed feeding tube 4 enters the inside of the mobile feeding tube 5 directly through the opening without falling. The mobile vibrator 6 is connected to the mobile feeding tube 5, the materials located in the mobile feeding tube 5 vibrate due to the vibration of the mobile vibrator 6, and the materials are conveyed, so that the materials in the mobile feeding tube 5 are conveyed into the quartz crucible. The mobile vibrator 6 is a vibrator, which is a commercially available product, and is selectively provided according to actual requirements, and no specific requirements are made herein. As shown in FIG. 2, the moving device may include a mobile connection device 12 and a mobile slide rail 13. The moving device described above is connected to the mobile feeding tube 5, and the mobile feeding tube 5 moves under the action of the moving device, moves from the inside of the charger body 1 to the inside of the monocrystal furnace 8, and moves to the upper part of the quartz crucible, so as to perform the re-feeding of the material. The moving device may be a cylinder, a hydraulic cylinder, a guide rail slider structure, a lead screw transmission, or other structure capable of moving the mobile feeding tube 5. The moving device may be selected according to actual requirements, and it is not specifically required herein. The mobile conveyer may be mounted on a table located in the charger body 1 so that the mobile conveyer is mounted inside the charger body 1.

In this case, as shown in FIG. 2, the charger body 1 includes a housing 17 and a connecting channel 15, the connecting channel 15 is connected to the housing 17, and the housing 17 is in communication with the connecting channel 15. The discharging end (i.e., the second discharging end) of the mobile feeding tube 5 is provided in the connecting channel 15, the storage 2 and the fixed conveyer are both installed in the housing 17, the mobile conveyer is installed in the housing 17, and the discharging end of the mobile feeding tube 5 partially extends into the connecting channel 1, so that the discharging end of the mobile feeding tube 5 enters into the monocrystal furnace 8 when the switching device 7 is opened. An end of the connecting channel 15 which is not connected to the housing 17 is connected to the switching device 7, a through hole is formed in the furnace body of the monocrystal furnace 8, and the switching device 7 is connected to the through hole. When the switching device 7 is opened, the switching device 7 communicates with the through hole and the connecting channel 15, respectively. At the same time, a thermal insulation layer in the monocrystal furnace 8 is also provided with a through hole at the position corresponding to this through hole, so that the mobile feeding tube 5 enters the monocrystal furnace 8 through this through hole via the connecting channel 15 during the moving process, and the materials are re-fed.

However, the embodiment according to the present disclosure is not limited to the above description, and various modifications and substitutions may be made to the structure of the mobile conveyer without departing from the scope of the present disclosure.

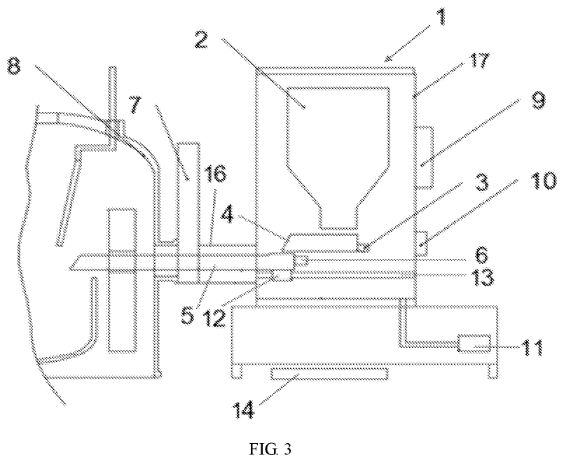

Alternatively, as shown in FIG. 3, the mobile conveyer includes a mobile feeding tube 5, a mobile vibrator 6, and a moving device (for example, the external moving device 14 shown in FIG. 3), the mobile vibrator 6 is connected to the mobile feeding tube 5, the charger body 1 is connected to the moving device, the charger body 1 and the mobile feeding tube 5 move toward the monocrystal furnace 8 under the action of the moving device, the mobile feeding tube 5 may enter the monocrystal furnace 8, and the feeding is carried out under the action of the mobile vibrator 6. In this structure, the moving device is connected to the charger body 1, the mobile feeding tube 5 is connected to the mobile vibrator 6, and the mobile feeding tube 5 and the fixed feeding tube 4 are relatively fixed without moving. The mobile feeding tube 5 is of a pipe structure, and an opening is provided at a position of the mobile feeding tube 5 corresponding to the discharging end of the fixed feeding tube 4, so that the materials flowing out from the fixed feeding tube 4 may enter the mobile feeding tube 5 and move along the length of the mobile feeding tube 5, and the materials are conveyed. The mobile vibrator 6 is a vibrator for vibrating and conveying the materials in the mobile feeding tube 5 under the action of the vibrator, and the vibrator is a commercially available product, and is selectively provided according to actual requirements, which is not specifically required herein. The mobile feeding tube 5 is fixedly mounted inside the charger body 1 by a mounting table, and the discharging end of the mobile feeding tube 5 extends to the outside of the charger body 1, so that the mobile feeding tube 5 may enter into the monocrystal furnace 8 to carry out the re-feeding of materials during the movement of the charger body 1. The moving device (external moving device 14 as shown in FIG. 3) is connected to the charger body 1 so that the charger body 1 moves relatively close to or away from the monocrystal furnace 8 under the action of the moving device, thereby enabling the mobile feeding tube 5 to enter or leave the monocrystal furnace 8. The moving device may be a lead screw transmission, a guide rail slider structure, an air cylinder, a hydraulic cylinder, an AGV (Automated Guided Vehicle), or another structure, which is selected according to actual requirements, no specific requirements are made herein. Since the storage 2 and the fixed conveyer are both located inside the charger body 1, the moving conveyer is located inside the charger body 1, and neither the mobile feeding tube 5 nor the mobile vibrator 6 can move relative to the charger body 1, so that the storage 2, the fixed conveyer, the mobile feeding tube 5 and the mobile vibrator 6 move with the movement of the charger body 1, thereby enabling the mobile feeding tube 5 to enter the monocrystal furnace 8 to perform material re-feeding.

In this configuration, as shown in FIG. 3, the charger body 1 includes a housing 17 and a telescopic member 16, the telescopic member 16 is connected to the housing 17, and the housing 17 communicates with the telescopic member 16. The discharging end of the mobile feeding tube 5 is provided inside the telescopic member 16, the telescopic member 16 is a pipe structure, one end of the telescopic member 16 is connected to and communicates with the housing 17, the other end of the telescopic member 16 is connected to the switching device 7, the telescopic member 16 communicates with the housing 17, and the position of the telescopic member 16 corresponds to the position of the mobile feeding tube 5. The discharging end of the mobile feeding tube 5 is located in the telescopic member 16. When the material re-feeding is required to be performed, the moving device moves the charger body 1 in the direction toward the monocrystal furnace 8, so that the mobile feeding tube 5 moves in the direction toward the monocrystal furnace 8, and the telescopic member 16 is compressed. The discharging end of the mobile feeding tube 5 enters the interior of the monocrystal furnace 8 through the switching device 7 and the through hole of the monocrystal furnace 8, and is located above the upper portion of the quartz crucible, so as to perform material re-feeding. After the re-feeding is completed, the charger body 1 moves away from the monocrystal furnace 8, the mobile feeding tube 5 moves out of the monocrystal furnace 8, and the switching device 7 is closed, thereby completing the material re-feeding. The telescopic member 16 is, for example, a bellows, which is a commercially available product, and is selected according to actual requirements, and it is not specifically required herein.

In some embodiments of the present disclosure, the above-mentioned switching device 7 is a valve, for example, a gate valve, which is a commercially available product, and is selected according to actual requirements, and it is not specifically required herein.

In some embodiments of the present disclosure, the pressure controller 11 described above is a vacuum pump. The vacuum pump is connected to the housing 17 of the charger body 1 through a connecting pipe to vacuum the inside of the charger body 1 and adjust the pressure of the inside of the charger body 1, so that the pressure inside the charger body 1 is consistent with the pressure of the monocrystal furnace 8, and the pressure of the monocrystal furnace 8 is not affected during the material re-feeding, thereby ensuring that the subsequent pulling of the monocrystal may be performed smoothly and reducing the time for pressure adjustment in the monocrystal furnace 8.

In some embodiments of the present disclosure, the charger body 1 is further provided with a pressure measuring instrument, for example, a pressure gauge, for detecting the pressure in the charger body 1, so as to be able to prepare to control the operation of the pressure controller 11, so that the pressure controller 11 may accurately and quickly adjust the pressure in the charger body 1 to coincide with the pressure of the monocrystal furnace 8.

In some embodiments of the present disclosure, an observation window 10 is also provided on the housing 17 of the charger body 1. The observation window 10 corresponds to the position of the fixed feeding tube 4. The fixed feeding tube 4 is observed when the materials flowing out from the storage 2 enters the fixed feeding tube 4, so that the degree of opening of the valve at the discharging end of the storage 2 is controlled to avoid accumulation of the materials due to excessive amount of the materials, and to avoid falling of the materials.

In some embodiments of the present disclosure, the external re-feeding apparatus further includes a controller electrically connected to the pressure controller 11, the fixed conveyer, the mobile conveyer, the storage 2, and the pressure measuring instrument, respectively, to receive a detection signal from the pressure measuring instrument, and to control the operations of the pressure controller 11, the fixed conveyer, the mobile conveyer, and the storage 2. At the same time, the controller 11 is connected to the control system of the monocrystal furnace 8 to receive a measurement result of the pressure in the monocrystal furnace 8, or the controller 11 may input the pressure in the monocrystal furnace 8, the pressure measuring instrument detects the pressure in the charger body 1 in real time, and transmits the measurement result to the controller. The controller compares the measurement result of the pressure measuring instrument with the pressure in the monocrystal furnace 8, and controls the operation of the pressure controller 11. When the pressure in the charger body 1 is consistent with the pressure in the monocrystal furnace 8, the controller controls the operation of the storage 2, the materials flow out from the storage 2 and enter the fixed conveyer, and the controller controls the operation of the fixed conveyer and the mobile conveyer so as to perform the re-feeding of the materials. The controller is, for example, a PLC controller.

In some embodiments of the present disclosure, the housing 17 of the charger body 1 is provided with a control screen 9 connected to the controller for displaying the relevant parameters and the relevant command input.

Furthermore, the embodiment according to the present disclosure is not limited to the above description, and various modifications and substitutions may be made to the structure and arrangement of the components of the external re-feeding apparatus without departing from the scope of the present disclosure.

When the external re-feeding apparatus is in operation, the pressure measuring instrument measures the pressure in the charger body 1 in real time, and transmits the measurement result to the controller. The controller compares the measurement result with the pressure in the monocrystal furnace 8, controls the operation of the pressure controller 11 to evacuate the charger body 1, and controls the pressure in the charger body 1 so that the pressure in the charger body 1 is consistent with the pressure in the monocrystal furnace 8. At this time, the switching device 7 is opened so that the monocrystal furnace 8 communicates with the charger body 1, the controller controls the storage 2, the fixed conveyer, and the mobile conveyer, the moving device moves the mobile feeding tube 5 in the direction toward the monocrystal furnace 8, the discharging end of the mobile feeding tube 5 enters the monocrystal furnace 8, and is positioned above the quartz crucible, and the moving device stops the operation. The valve at the discharging end of the storage 2 is opened, the material enters the fixed feeding tube 4, the fixed vibrator 3 vibrates, the material moves along the fixed feeding tube 4 and enters the mobile feeding tube 5, the mobile vibrator 6 vibrates, the material moves along the mobile feeding tube 5, and the material flows out from the mobile feeding tube 5 and enters the quartz crucible for re-feeding the material. Upon completion of the re-feeding, the moving device operates to move the mobile feeding tube 5 away from the monocrystal furnace 8 and out of the monocrystal furnace 8, and the switching device 7 is closed to complete the re-feeding of the material. Of course, as a result of the action of the pressure controller 11, the mobile feeding tube 5 may not be removed from the monocrystal furnace 8 after the completion of one re-feeding, so that the next re-feeding may be performed, and the mobile feeding tube 5 may be removed from the monocrystal furnace 8 until the monocrystal pulling is completed.

With the above-mentioned technical solution, the external re-feeding apparatus is simple in structure, convenient to use, and includes a storage, so that materials may be stored, thereby meeting the requirements of continuous re-feeding. The external re-feeding apparatus has a fixed conveyer and a mobile conveyer for conveying materials, the mobile conveyer is provided with a mobile feeding tube, the mobile feeding tube may be moved relative to the monocrystal furnace, and the mobile feeding tube may be moved relatively close to or far away from the monocrystal furnace, so that the mobile feeding tube may enter the monocrystal furnace during the re-feeding, the materials may be moved along the mobile feeding tube to be re-fed. The storage, the fixed conveyer and the mobile conveyer cooperate with each other, so that continuous feeding of the materials may be realized, and waste of work time caused by shutdown may be avoided. The fixed conveyer and the mobile conveyer are arranged so that the quantity of the material entering the quartz crucible is small, continuous re-feeding is performed, and when the material is put into the quartz crucible, impact on the quartz crucible is reduced, and sputtering of the silicon melt does not occur. In addition, the fixed conveyer and the mobile conveyer are used for re-feeding the materials, so that the materials may be supplied in an intermittent manner or in a continuous manner, thereby meeting the production requirements.

The embodiments of the present disclosure have been described in detail above, but are merely exemplary embodiments of the disclosure and are not to be considered as limiting the disclosure. All equivalents and modifications made in accordance with the scope of the present disclosure shall remain within the scope of the present disclosure.

1. Raw material re-feeding apparatus disposed outside a monocrystal furnace, comprising:
a charger body;
a storage disposed in the charger body;
a conveyer disposed in the charger body and configured to convey raw materials, wherein a charging end of the conveyer is aligned with a discharging end of the storage to receive the raw materials supplied from the storage;
a switching device disposed between the monocrystal furnace and the charger body, connected to the charger body and the monocrystal furnace, and configured to control connection/disconnection between the charger body and the monocrystal furnace; and
a moving device configured to drive the conveyer to move a discharging end of the conveyer from outside of the monocrystal furnace to inside of the monocrystal furnace.

2. The raw material re-feeding apparatus according to claim 1, wherein the conveyer comprises:
a fixed conveyer disposed in the charger body and below the storage, wherein the fixed conveyer comprises a first charging end and a first discharging end, and the first charging end constitutes the charging end of the conveyer; and
a mobile conveyer comprising a second charging end and a second discharging end, wherein the second charging end is aligned with the first discharging end to receive the raw materials supplied by the fixed conveyer, and the second discharging end constitutes the discharging end of the conveyer.

3. The raw material re-feeding apparatus according to claim 2, wherein the mobile conveyer comprises a mobile feeding tube and a mobile vibrator connected to the mobile feeding tube, the second charging end and the second discharging end are respectively provided at opposite ends of the mobile feeding tube, and the mobile vibrator is configured to generate vibration and cause the raw materials to be conveyed under the vibration.

4. The raw material re-feeding apparatus according to claim 2, wherein the moving device is located in the charger body and connected to the mobile conveyer, and the moving device is configured to move the mobile conveyer relative to the fixed conveyer to enter the monocrystal furnace, and
wherein the second charging end of the mobile conveyer is at least partially aligned with the first discharging end of the fixed conveyer during movement of the mobile conveyer.

5. The raw material re-feeding apparatus according to claim 4, wherein the charger body comprises a housing and a connecting channel, one end of the connecting channel is connected to the housing, another end of the connecting channel is connected to the switching device, and when the switching device is closed, the second discharging end of the mobile conveyer is located in the connecting channel.

6. The raw material re-feeding apparatus according to claim 1, wherein the conveyer is connected to the charger body, the moving device is connected to the charger body, and the moving device is configured to move the charger body and the conveyer toward the monocrystal furnace and to move the discharging end of the conveyer to enter the monocrystal furnace.

7. The raw material re-feeding apparatus according to claim 6, wherein the charger body comprises a housing and a telescopic member, one end of the telescopic member is connected to the housing, another end of the telescopic member is connected to the switching device, and when the switching device is closed, the discharging end of the conveyer is located inside the telescopic member.

8. The raw material re-feeding apparatus according to claim 2, wherein the fixed conveyer comprises a fixed feeding tube and a fixed vibrator, the fixed feeding tube is connected to the fixed vibrator, and the raw materials in the fixed feeding tube are capable of being conveyed to the mobile conveyer under action of the fixed vibrator.

9. The raw material re-feeding apparatus according to claim 1, further comprising a pressure controller and a pressure measuring instrument connected to the charger body,
wherein the pressure controller is configured to control pressure in the charger body.

10. The raw material re-feeding apparatus according to claim 9, further comprising a controller electrically connected to the pressure controller, the conveyer, the moving device, the storage and the pressure measuring instrument for receiving a detection signal from the pressure measuring instrument and controlling operations of the pressure controller, the conveyer, the moving device, and the storage.

11. Monocrystal manufacturing apparatus comprising:
a monocrystal furnace; and
a raw material re-feeding apparatus disposed outside the monocrystal furnace,
wherein the raw material re-feeding apparatus comprises:
a charger body;
a storage disposed in the charger body;
a conveyer disposed in the charger body and configured to convey raw materials, wherein a charging end of the conveyer is aligned with a discharging end of the storage to receive the raw materials supplied from the storage;
a switching device disposed between the monocrystal furnace and the charger body, connected to the charger body and the monocrystal furnace, and configured to control connection/disconnection between the charger body and the monocrystal furnace; and
a moving device configured to drive the conveyer to move a discharging end of the conveyer from outside of the monocrystal furnace to inside of the monocrystal furnace.

12. Raw material re-feeding apparatus disposed outside a monocrystal furnace, the raw material re-feeding apparatus comprising a charger body, a storage, a fixed conveyer, a mobile conveyer, a switching device, and a pressure controller, wherein
the fixed conveyer and the storage are disposed in the charger body, and a charging end of the fixed conveyer is arranged to be aligned with a discharging end of the storage;
a charging end of the mobile conveyer is arranged to be aligned with a discharging end of the fixed conveyer, and the mobile conveyer is movable in a direction toward the monocrystal furnace, to enable raw materials flowing out of the fixed conveyer to fall onto the mobile conveyer and to be conveyed into the monocrystal furnace for feeding under action of the mobile conveyer;
the pressure controller is connected to the charger body for controlling pressure in the charger body; and
the switching device is connected to the charger body and the monocrystal furnace for achieving connection/disconnection between the charger body and the monocrystal furnace.

13. The raw material re-feeding apparatus according to claim 12, wherein the mobile conveyer comprises a mobile feeding tube, a mobile vibrator and a moving device, the mobile vibrator is connected to the mobile feeding tube, the mobile feeding tube is connected to the moving device, the mobile feeding tube is movable relative to the fixed conveyer under action of the moving device, and a charging end of the mobile feeding tube is at least partially aligned with a discharging end of the fixed conveyer during movement of the mobile feeding tube, to enable the mobile feeding tube to enter the monocrystal furnace for feeding under action of the mobile vibrator.

14. The raw material re-feeding apparatus according to claim 13, wherein the charger body comprises a housing and a connecting channel, the connecting channel is connected to the housing, the housing communicates with the connecting channel, and a discharging end of the mobile feeding tube is disposed in the connecting channel.

15. The raw material re-feeding apparatus according to claim 12, wherein the mobile conveyer comprises a mobile feeding tube, a mobile vibrator and a moving device, the mobile vibrator is connected to the mobile feeding tube, the mobile feeding tube is connected to the charger body, the charger body is connected to the moving device, and the charger body is movable toward the monocrystal furnace under action of the moving device, to enable the mobile feeding tube to enter the monocrystal furnace for feeding under action of the mobile vibrator.

16. The raw material re-feeding apparatus according to claim 15, wherein the charger body comprises a housing and a telescopic member, the telescopic member is connected to the housing, the housing communicates with the telescopic member, and a discharging end of the mobile feeding tube is disposed in the telescopic member.

17. The raw material re-feeding apparatus according to claim 12, wherein the fixed conveyer comprises a fixed feeding tube and a fixed vibrator, the fixed feeding tube is connected to the fixed vibrator, and the raw materials in the fixed feeding tube are capable of being conveyed to the mobile conveyer under action of the fixed vibrator.

18. The raw material re-feeding apparatus according to claim 17, wherein a pressure measuring instrument is disposed on the charger body.

19. The raw material re-feeding apparatus according to claim 18, further comprising a controller electrically connected to the pressure controller, the fixed conveyer, the mobile conveyer, the storage and the pressure measuring instrument for receiving a detection signal from the pressure measuring instrument and controlling operations of the pressure controller, the fixed conveyer, the mobile conveyer, and the storage.
